(19) United States
(12) Patent Application Publication
(10) Pub. No.: US 2010/0167206 A1
(43) Pub. Date: Jul. 1, 2010

(54) PHOTORESIST COMPOSITION AND METHOD FOR MANUFACTURING A DISPLAY SUBSTRATE USING THE PHOTORESIST COMPOSITION

(75) Inventors: Woo-Seok JEON, Seongnam-si (KR); Sang-Hyun YUN, Suwon-si (KR); Hi-Kuk LEE, Yongin-si (KR); Deok-Man KANG, Seongnam-si (KR); Sae-Tae OH, Pyeongtaek-si (KR)

Correspondence Address: H.C. PARK & ASSOCIATES, PLC, 8500 LEESBURG PIKE, SUITE 7500, VIENNA, VA, 22182, US

(73) Assignees: SAMSUNG ELECTRONICS CO., LTD., Suwon-si (KR); AZ ELECTRONIC MATERIALS (JAPAN) K.K., Tokyo (JP)

(21) Appl. No.: 12/557,215

(22) Filed: Sep. 10, 2009

(30) Foreign Application Priority Data
Dec. 29, 2008 (KR) 2008-135123

(51) Int. Cl. G03F 7/20; G03F 7/004

(52) U.S. Cl. 430/281.1; 430/313

(57) ABSTRACT

A photoresist composition includes a novolac resin, a benzophenone photosensitizer and an ethylidyne tris phenol photosensitizer, and an organic solvent. Thus, a micropattern having a higher resolution than the resolution of an exposure apparatus is formed to decrease an amount of exposure and/or exposure time, thereby improving manufacturing reliability and productivity.

### CROSS REFERENCE TO RELATED APPLICATION

This application claims priority from and the benefit of Korean Patent Application No. 2008-135123, filed on Dec. 29, 2008, which is hereby incorporated by reference for all purposes as if fully set forth herein.

### BACKGROUND OF THE INVENTION

1. Field of the Invention

The present invention relates to a photoresist composition and a method for manufacturing a display substrate. More particularly, embodiments of the present invention relate to a photoresist composition for manufacturing a liquid crystal display (LCD) device and a method for manufacturing a display substrate.

2. Discussion of the Background

Generally, a liquid crystal display (LCD) panel includes an array substrate having a thin-film transistor (TFT) as a switching element to drive a pixel, an opposing substrate facing the array substrate, and a liquid crystal layer interposed between the array substrate and the opposing substrate. An image is displayed on the LCD panel according to the light transmittance of the liquid crystal layer, which changes according to voltages applied thereto.

The array substrate includes a gate pattern, a source pattern formed on the gate pattern, and a pixel electrode formed on the source pattern. The gate pattern may include a gate line and a gate electrode of a switching element. The gate electrode is connected to the gate line. The source pattern may include a data line crossing the gate line, a source electrode and a drain electrode. The switching element includes the source and drain electrodes with the gate electrode. The source electrode is connected to the data line. The drain electrode is spaced apart from the source electrode. The pixel electrode electrically contacts the drain electrode to be electrically connected to the switching element and to receive a data signal when the switching element is switched on. Each of the gate pattern, the source pattern and the pixel electrode may be formed by patterning a thin layer through a photolithography process.

Recently, an LCD panel including a gate line and a data line having narrow widths for decreasing a pixel size and an LCD panel of a patterned vertical alignment (PVA) mode, in which pixel electrodes have fine patterns for improving a viewing angle, have become favored. In order to manufacture the LCD panels, an exposure apparatus having a high resolution may be used, or an amount of exposure may be increased.

However, an exposure apparatus having a low resolution is more practical when mass-producing the LCD panels. Thus, there are limits to forming an electrode and/or a line having a width below about 10 μm. To solve the above problems, when the exposure apparatus having a low resolution is replaced with the exposure apparatus having a high resolution, manufacturing costs may be increased, because the exposure apparatus having a high resolution is more expensive than the exposure apparatus having a low resolution. In addition, when the amount of exposure is increased, the tact time of the exposure apparatus may be increased so that the manufacturing time is lengthened.

### SUMMARY OF THE INVENTION

Exemplary embodiments of the present invention provide a photoresist composition for forming a micropattern having a high resolution.

Exemplary embodiments of the present invention also provide a method for manufacturing a display substrate using the photoresist composition.

Additional features of the invention will be set forth in the description which follows, and in part will be apparent from the description, or may be learned by practice of the invention.

An exemplary embodiment of the present invention discloses, a) a photoresist composition includes a novolac resin, b) a benzophenone photosensitizer and an ethylidyne tris phenol photosensitizer in a weight ratio between about 20:80 to about 80:20 based on a total weight of the benzophenone photosensitizer and the ethylidyne tris phenol photosensitizer, and c) an organic solvent.

An exemplary embodiment of the present invention also discloses a method for manufacturing a display substrate using a photoresist composition. A transparent electrode layer is formed on a base substrate including a switching element connected to a gate line and a data line. A photoresist pattern is formed on the base substrate including the transparent electrode layer. The photoresist pattern is formed using a photoresist composition including a) a novolac resin, b) a benzophenone photosensitizer and an ethylidyne tris phenol photosensitizer in a weight ratio between about 20:80 to about 80:20 based on a total weight of the benzophenone photosensitizer and the ethylidyne tris phenol photosensitizer, and c) an organic solvent. The transparent electrode layer is patterned by using the photoresist pattern as an etching mask to form a pixel electrode including a plurality of microelectrodes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view illustrating a display panel according to an exemplary embodiment of the present invention.

FIG. 2 is a cross-sectional view taken along line I-I′ in FIG. 1.

FIG. 3, FIG. 4 and FIG. 5 are cross-sectional views illustrating a method for manufacturing the display substrate shown in FIG. 2 according to an exemplary embodiment of the present invention.

### DETAILED DESCRIPTION OF THE ILLUSTRATED EMBODIMENTS

The invention is described more fully hereinafter with reference to the accompanying drawings, in which example embodiments of the invention are shown. The invention may, however, be embodied in many different forms and should not be construed as limited to the embodiments set forth herein. Rather, these embodiments are provided so that this disclosure is thorough, and will fully convey the scope of the present invention to those skilled in the art. In the drawings, the size and relative sizes of layers and regions may be exaggerated for clarity. Like reference numerals in the drawings denote like elements.

It will be understood that when an element or layer is referred to as being “on,” “connected to” or “coupled to” another element or layer, it can be directly on, connected to or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Photoresist Composition

A photoresist composition includes a) a novolac resin, b) a photosensitizer, and c) an organic solvent.

a) Novolac Resin

The novolac resin may be prepared by reacting a phenol compound with an aldehyde compound or a ketone compound in the presence of an acidic catalyst.

The phenol compound includes an m-cresol and a p-cresol.

Examples of the aldehyde compound may include formaldehyde, formalin, p-formaldehyde, trioxane, acetaldehyde, benzaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, terephthalic acid aldehyde, etc. These can be used alone or in a combination thereof.

Examples of the ketone compound may include acetone, methylethylketone, diethyl ketone, diphenyl ketone, etc. These can be used alone or in a combination thereof.

When a content of the m-cresol is less than about 40 percent by weight and a content of the p-cresol is greater than about 60 percent by weight based on a total weight of the phenol compound, a photosensitizing speed of the photoresist composition is excessively low so that the photoresist composition may not be available in a photolithography process. When a content of the m-cresol is greater than about 60 percent by weight and a content of the p-cresol is less than about 40 percent by weight based on a total weight of the phenol compound, the resolution of a photoresist film formed from the photoresist composition is lowered. Thus, a weight ratio of the m-cresol to the p-cresol may be in a range from about 40:60 to about 60:40. In an example embodiment, the weight ratio of the m-cresol to the p-cresol may be about 50:50.

When a weight average molecular weight of the novolac resin is less than about 3,000, the dissolving rate of the novolac resin in a developing solution increases so that the photosensitivity of the photoresist composition may be difficult to control, and a difference between an exposed portion and an unexposed portion of the photoresist pattern may be reduced so that a photoresist pattern having a clear pattern may be difficult to form. When a weight average molecular weight of the novolac resin is greater than about 15,000, the dissolving rate of the novolac resin in a developing solution is slowed so that a photoresist pattern may be difficult to form. Thus, a weight average molecular weight of the novolac resin may be in a range from about 3,000 to about 15,000.

When a content of the novolac resin is less than about 5 percent by weight based on a total weight of the photoresist composition, the viscosity of the photoresist composition is excessively low so that it is difficult to form a photoresist layer having a predetermined thickness. When a content of the novolac resin is greater than about 20 percent by weight based on a total weight of the photoresist composition, the viscosity of the photoresist composition is excessively high so that the photoresist composition may be difficult to coat on a substrate. Thus, a content of the novolac resin may be in a range from about 5 percent by weight to about 20 percent by weight of the photoresist composition.

b) Photosensitizer

The photosensitizer may control a photosensitizing speed. The photosensitizer includes a benzophenone photosensitizer and an ethylidyne tris phenol photosensitizer.

The benzophenone photosensitizer may be prepared by reacting a benzophenone compound with a quinone diazide compound. Examples of the benzophenone compound may include 2,3,4-trihydroxybenzophenone, 2,3,4,4′-tetrahydroxybenzophenone, etc. Examples of the quinone diazide compound may include sulfonic ester of quinone diazide derivatives such as 1,2-benzoquinonediazide-4-sulfonic ester, 1,2-naphtoquinonediazide-4-sulfonic ester, etc.; and sulfonic chloride of quinone diazide derivatives such as 1,2-benzoquinone-2-diazide-4-sulfonic chloride, 1,2-naphtoquinone-2-diazide-4-sulfonic chloride, 1,2-naphtoquinone-diazide-5-sulfonic chloride, 1,2-naphtoquinone-1-diazide-6-sulfonic chloride, 1,2-benzoquinone-1-diazide-5-sulfonic chloride, etc. These can be used alone or in a combination thereof.

In an example embodiment, the benzophenone photosensitizer is prepared by reacting 2,3,4,4′-tetrahydroxybenzophenone with naphtoquinone-1,2-diazide-5-sulfonyl chloride. The benzophenone photosensitizer may further include 2,3,4,4′-tetrahydroxybenzophenone and/or naphtoquinone- 1,2-diazide-5-sulfonyl chloride, except for a compound produced by the above reaction.

The ethylidyne tris phenol photosensitizer may be prepared by reacting an ethylidyne tris phenol compound with a quinone diazide compound. For example, the ethylidyne tris phenol compound may include 4,4′,4″-ethylidyne tris phenol. Examples of the quinone diazide compound may include sulfonic ester of quinone diazide derivatives such as 1,2-benzoquinonediazide-4-sulfonic ester, 1,2-naphtoquinonediazide-4-sulfonic ester, etc.; and sulfonic chloride of quinone diazide derivatives such as 1,2-benzoquinone-2-diazide-4-sulfonic chloride, 1,2-naphtoquinone-2-diazide-4-sulfonic chloride, 1,2-naphtoquinone-diazide-5-sulfonic chloride, 1,2-naphtoquinone-1-diazide-6-sulfonic chloride, 1,2-benzoquinone-1-diazide-5-sulfonic chloride, etc. These can be used alone or in a combination thereof.

In an example embodiment, the ethylidyne tris phenol photosensitizer is prepared by reacting 4,4′,4″-ethylidyne tris phenol with 1,2-naphtoquinone-diazide-5-sulfonic chloride. The ethylidyne tris phenol photosensitizer may further include 2,3,4,4′-tetrahydroxybenzophenone and/or naphtoquinone-1,2-diazide-5-sulfonyl chloride, except for a compound produced by the above reaction.

When a content of the benzophenone photosensitizer is less than about 20 percent by weight and a content of the ethylidyne tris phenol photosensitizer is greater than about 80 percent by weight based on a total weight of the photosensitizer, the photosensitivity of the photoresist composition may be hardly improved by the benzophenone photosensitizer and the photosensitivity of the photoresist composition is excessively lowered to increasing a tact time of the exposure process in the photolithography process, thereby increasing the process time. When a content of the benzophenone photosensitizer is greater than about 80 percent by weight and a content of the ethylidyne tris phenol photosensitizer is less than about 20 percent by weight based on a total weight of the photosensitizer, the photosensitivity of the photoresist composition is excessively increased so that it is difficult to control the patterning process of the photoresist layer, and the resolution of the photoresist composition may be hardly improved. Thus, a weight ratio of the benzophenone photosensitizer to the ethylidyne tris phenol photosensitizer may be in a range from about 20:80 to about 80:20.

When a content of the photosensitizer is less than about 2 percent by weight based on a total weight of the photoresist composition, the weight of the photosensitizer is excessively small so that the photoresist composition is not activated by light. When a content of the photosensitizer is greater than about 10 percent by weight based on a total weight of the photoresist composition, the photosensitivity of the photoresist composition increases so that it is difficult to control the photosensitivity of the photoresist composition. Thus, a content of the photosensitizer may be in a range from about 2 percent by weight to about 10 percent by weight based on a total weight of the photoresist composition. Preferably, a content of the photosensitizer is in a range from about 4 percent by weight to about 6 percent by weight based on a total weight of the photoresist composition.

c) Organic Solvent

Examples of the organic solvent may include alcohols such as methanol and ethanol, ethers such as tetrahydrofurane, glycol ethers such as ethylene glycol monomethyl ether and ethylene glycol monoethyl ether, ethylene glycol alkyl ether acetates such as methyl cellosolve acetate and ethyl cellosolve acetate, diethylene glycols such as diethylene glycol monomethyl ether, diethylene glycol monoethyl ether, and diethylene glycol dimethyl ether, propylene glycol monoalkyl ethers such as propylene glycol methyl ether, propylene glycol ethyl ether, propylene glycol propyl ether, and propylene glycol butyl ether, propylene glycol alkyl ether acetates such as propylene glycol methyl ether acetate, propylene glycol ethyl ether acetate, propylene glycol propyl ether acetate, and propylene glycol butyl ether acetate, propylene glycol alkyl ether propionates such as propylene glycol methyl ether propionate, propylene glycol ethyl ether propionate, propylene glycol propyl ether propionate, and propylene glycol butyl ether propionate, aromatic compounds such as toluene and xylene, ketones such as methyl ethyl ketone, cyclohexanone, and 4-hydroxy-4-methyl-2-pentanone, and ester compounds such as methyl acetate, ethyl acetate, propyl acetate, butyl acetate, ethyl 2-hydroxypropionate, methyl 2-hydroxy-2-methyl propionate, ethyl 2-hydroxy-2-methyl propionate, methyl hydroxyacetate, ethyl hydroxyacetate, butyl hydroxyacetate, methyl lactate, ethyl lactate, propyl lactate sulfate, butyl lactate, methyl 3-hydroxypropionate, ethyl 3-hydroxypropionate, propyl 3-hydroxypropionate, butyl 3-hydroxypropionate, methyl 2-hydroxy-3-methyl butanoate, methyl methoxyacetate, ethyl methoxyacetate, propyl methoxyacetate, butyl methoxyacetate, methyl ethoxyacetate, ethyl ethoxyacetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2- ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate. These can be used alone or in a combination thereof.

Preferably, glycol ethers, ethylene glycol alkyl ether acetates and diethylene glycols are used as the organic solvent, because glycol ethers, ethylene glycol alkyl ether acetates and diethylene glycols have good solubility and reactivity and easily form a coating layer. More preferably, propylene glycol methyl ether acetate is used as the organic solvent.

For example, when a total weight of the photoresist composition including the organic solvent, the novolac resin and the photosensitizer is considered to be 100 percent, about 85 percent by weight of the organic solvent may be added to about 10 percent by weight of the novolac resin and about 5 percent by weight of the photosensitizer. When a content of the organic solvent is less than about 75 percent by weight of the photoresist composition, a content of the novolac resin and/or the photosensitizer is relatively increased so that the viscosity of the photoresist composition is increased. Thus, it is difficult to coat the photoresist composition uniformly. When a content of the organic solvent is greater than about 90 percent by weight of the photoresist composition, a content of the novolac resin and/or the photosensitizer is relatively decreased so that the resolution and/or the photosensitivity of the photoresist composition may be lacking. Thus, a content of the organic solvent may be in a range from about 75 percent by weight to about 90 percent by weight of the photoresist composition.

d) Additive

The photoresist composition may further include an additive such as an adhesion promoter agent, a surfactant, dye, etc. The additive may improve the performance of the photoresist composition, which may be desired according to the processes in the photolithography process. A content of the additive may be in a range to about 5 percent by weight based on a total weight of the photoresist composition.

The adhesion promoter agent may improve an adhesion between a substrate and a photoresist pattern formed from the photoresist composition. Examples of the adhesion promoter agent may include a silane coupling agent including a reactive substitution group such as a carboxyl group, a methacryl group, an isocyanate group, an epoxy group, etc. Particularly, examples of the silane coupling agent may include γ-methacryloxypropyl trimethoxysilane, vinyl triacetoxy silane, vinyl trimethoxysilane, γ-isocyanate propyl triethoxysilane, γ-glycidoxypropyl trimethoxysilane, β-(3,4-epoxycyclohexyl)ethyl trimethoxysilane, etc. These can be used alone or in a combination thereof.

The surfactant may improve coating characteristics and development characteristics of the photoresist composition. Examples of the surfactant may include polyoxyethylene octylphenylether, polyoxyethylene nonylphenylether, F171, F172, F173 (trade name, manufactured by Dainippon Ink in Japan), FC430, FC431 (trade name, manufactured by Sumitomo 3M in Japan), KP341 (trade name, manufactured by Shin-Etsu Chemical in Japan), etc. These can be used alone or in a combination thereof.

Hereinafter, a photoresist composition according to an exemplary embodiment of the present invention will be more fully described with reference to the following particular examples and Comparative Examples.

### Example 1

A phenol mixture including an m-cresol and a p-cresol in a weight ratio of about 60:40 was reacted with formaldehyde and oxalic acid to prepare a novolac resin, of which a weight average molecular weight was about 9,000. About 10 percent by weight of the novolac resin, about 4 percent by weight of a benzophenone photosensitizer prepared by reacting naphtoquinone 1,2-diazide-5-sulfonyl chloride and 2,3,4,4′-tetrahydroxybenzophenone, about 1 percent by weight of a ethylidyne tris phenol photosensitizer prepared by reacting 4,4′,4″-ethylidyne tris phenol and naphtoquinone 1,2-diazide-5-sulfonyl chloride and about 85 percent by weight of propylene glycol methyl ether acetate (PGMEA) were mixed with each other to prepare a photoresist composition. The viscosity of the obtained photoresist composition was about 15 centipoise (cP).

### Example 2

A photoresist composition was prepared through substantially the same method as Example 1, except for including about 3 percent by weight of the benzophenone photosensitizer and about 2 percent by weight of the ethylidyne tris phenol photosensitizer. The viscosity of the obtained photoresist composition was about 15 cP.

### Example 3

A photoresist composition was prepared through substantially the same method as Example 1, except for including about 2 percent by weight of the benzophenone photosensitizer and about 3 percent by weight of the ethylidyne tris phenol photosensitizer. The viscosity of the obtained photoresist composition was about 15 cP.

### Example 4

A photoresist composition was prepared by substantially the same method as Example 1, except for including about 1 percent by weight of the benzophenone photosensitizer and about 4 percent by weight of the ethylidyne tris phenol photosensitizer. The viscosity of the obtained photoresist composition was about 15 cP.

### Example 5

A photoresist composition was prepared by substantially the same method as Example 1, except for preparing the novolac resin using a phenol mixture including the m-cresol and the p-cresol in a weight ratio of about 50:50. The viscosity of the obtained photoresist composition was about 15 cP.

### Example 6

A photoresist composition was prepared by substantially the same method as Example 2, except for preparing the novolac resin using the phenol mixture including the m-cresol and the p-cresol in the weight ratio of about 50:50. The viscosity of the obtained photoresist composition was about 15 cP

### Example 7

A photoresist composition was prepared by substantially the same method as Example 3, except for preparing the novolac resin using the phenol mixture including the m-cresol and the p-cresol in the weight ratio of about 50:50. The viscosity of the obtained photoresist composition was about 15 cP.

### Example 8

A photoresist composition was prepared by substantially the same method as Example 4, except for preparing the novolac resin using the phenol mixture including the m-cresol and the p-cresol in the weight ratio of about 50:50. The viscosity of the obtained photoresist composition was about 15 cP.

### Example 9

A photoresist composition was prepared by substantially the same method as Example 1, except for preparing the novolac resin using a phenol mixture including the m-cresol and the p-cresol in a weight ratio of about 40:60. The viscosity of the obtained photoresist composition was about 15 cP.

### Example 10

A photoresist composition was prepared by a method substantially the same as Example 2, except for preparing the novolac resin using the phenol mixture including the m-cresol and the p-cresol in the weight ratio of about 40:60. The viscosity of the obtained photoresist composition was about 15 cP

### Example 11

A photoresist composition was prepared by substantially the same method as Example 3, except for preparing the novolac resin using the phenol mixture including the m-cresol and the p-cresol in the weight ratio of about 40:60. The viscosity of the obtained photoresist composition was about 15 cP.

### Example 12

A photoresist composition was prepared by substantially the same method as Example 4, except for preparing the novolac resin using the phenol mixture including the m-cresol and the p-cresol in the weight ratio of about 40:60. The viscosity of the obtained photoresist composition was about 15 cP.

### Example 13

A photoresist composition was prepared by substantially the same method as Example 1, except for preparing the novolac resin using a phenol mixture including the m-cresol and the p-cresol in a weight ratio of about 70:30. The viscosity of the obtained photoresist composition was about 15 cP.

### Example 14

A photoresist composition was prepared by substantially the same method as Example 2, except for preparing the novolac resin using the phenol mixture including the m-cresol and the p-cresol in the weight ratio of about 70:30. The viscosity of the obtained photoresist composition was about 15 cP.

### Example 15

A photoresist composition was prepared by substantially the same method as Example 3, except for preparing the novolac resin using the phenol mixture including the m-cresol and the p-cresol in the weight ratio of about 70:30. The viscosity of the obtained photoresist composition was about 15 cP.

### Example 16

A photoresist composition was prepared by substantially the same method as Example 4, except for preparing the novolac resin using the phenol mixture including the m-cresol and the p-cresol in the weight ratio of about 70:30. The viscosity of the obtained photoresist composition was about 15 cP.

### Example 17

A photoresist composition was prepared by substantially the same method as Example 1, except for preparing the novolac resin using a phenol mixture including the m-cresol and the p-cresol in a weight ratio of about 30:70. The viscosity of the obtained photoresist composition was about 15 cP.

### Example 18

A photoresist composition was prepared by substantially the same method as Example 2, except for preparing the novolac resin using the phenol mixture including the m-cresol and the p-cresol in the weight ratio of about 30:70. The viscosity of the obtained photoresist composition was about 15 cP.

### Example 19

A photoresist composition was prepared by substantially the same method as Example 3, except for preparing the novolac resin using the phenol mixture including the m-cresol and the p-cresol in the weight ratio of about 30:70. The viscosity of the obtained photoresist composition was about 15 cP.

### Example 20

A photoresist composition was prepared by substantially the same method as Example 4, except for preparing the novolac resin using the phenol mixture including the m-cresol and the p-cresol in the weight ratio of about 30:70. The viscosity of the obtained photoresist composition was about 15 cP.

### Comparative Example 1

A photoresist composition was prepared through substantially the same method as Example 1, except for including about 5 percent by weight of the benzophenone photosensitizer and not including the ethylidyne tris phenol photosensitizer. The viscosity of the obtained photoresist composition was about 15 cP.

### Comparative Example 2

A photoresist composition was prepared through substantially the same method as Example 1, except for including about 5 percent by weight of the ethylidyne tris phenol photosensitizer and not including the benzophenone photosensitizer. The viscosity of the obtained photoresist composition was about 15 cP.

### Comparative Example 3

A photoresist composition was prepared by substantially the same method as Comparative Example 1, except for preparing the novolac resin using the phenol mixture including the m-cresol and the p-cresol in the weight ratio of about 50:50. The viscosity of the obtained photoresist composition was about 15 cP.

### Comparative Example 4

A photoresist composition was prepared by substantially the same method as Comparative Example 2, except for preparing the novolac resin using the phenol mixture including the m-cresol and the p-cresol in the weight ratio of about 50:50. The viscosity of the obtained photoresist composition was about 15 cP.

### Comparative Example 5

A photoresist composition was prepared by substantially the same method as Comparative Example 1, except for preparing the novolac resin using the phenol mixture including the m-cresol and the p-cresol in the weight ratio of about 40:60. The viscosity of the obtained photoresist composition was about 15 cP.

### Comparative Example 6

A photoresist composition was prepared by substantially the same method as Comparative Example 2, except for preparing the novolac resin using the phenol mixture including the m-cresol and the p-cresol in the weight ratio of about 40:60. The viscosity of the obtained photoresist composition was about 15 cP.

### Comparative Example 7

A photoresist composition was prepared by substantially the same method as Comparative Example 1, except for preparing the novolac resin using the phenol mixture including the m-cresol and the p-cresol in the weight ratio of about 70:30. The viscosity of the obtained photoresist composition was about 15 cP.

### Comparative Example 8

A photoresist composition was prepared by substantially the same method as Comparative Example 2, except for preparing the novolac resin using the phenol mixture including the m-cresol and the p-cresol in the weight ratio of about 70:30. The viscosity of the obtained photoresist composition was about 15 cP.

### Comparative Example 9

A photoresist composition was prepared by substantially the same method as Comparative Example 1, except for preparing the novolac resin using the phenol mixture including the m-cresol and the p-cresol in the weight ratio of about 30:70. The viscosity of the obtained photoresist composition was about 15 cP.

### Comparative Example 10

A photoresist composition was prepared by substantially the same method as Comparative Example 2, except for preparing the novolac resin using the phenol mixture including the m-cresol and the p-cresol in the weight ratio of about 30:70. The viscosity of the obtained photoresist composition was about 15 cP.

Experiment

Each of photoresist compositions according to Examples 1 to 20 and Comparative Examples 1 to 10 was coated on a substrate having a transparent electrode layer which included indium zinc oxide (IZO) and had a thickness of about 500 Å to form a photoresist layer. The photoresist layer was exposed to light by using an FX-601 exposure system (trade name, manufactured by Nikon in Japan) having a numerical aperture (NA) of about 0.1 and was developed using tetramethyl ammonium hydroxide (TMAH) of about 2.38% for about 60 seconds.

The photosensitivity and the resolution of each photoresist composition were measured. The results thus obtained are shown in the following Table 1. In Table 1, the photosensitivity is represented by an energy (mJ) required in the exposure process so that the photoresist layer may be dissolved in the TMAH developer. The resolution is represented by a width (μm) of a photoresist pattern line formed through the exposure process and the developing process.

TABLE 1

| | Photosensitivity (mJ) | Resolution (μm) |
|---|---|---|
| Example 1 | 30 | 2.8 |
| Example 2 | 38 | 2.2 |
| Example 3 | 58 | 2.2 |
| Example 4 | 90 | 2.2 |
| Example 5 | 35 | 2.5 |
| Example 6 | 43 | 2.0 |
| Example 7 | 64 | 2.0 |
| Example 8 | 92 | 2.0 |
| Example 9 | 44 | 2.6 |
| Example 10 | 53 | 2.2 |
| Example 11 | 90 | 2.2 |
| Example 12 | 125 | 2.0 |
| Example 13 | 25 | 3.0 |
| Example 14 | 33 | 2.8 |
| Example 15 | 55 | 2.6 |
| Example 16 | 70 | 2.4 |
| Example 17 | 98 | 2.6 |
| Example 18 | 140 | 2.4 |
| Example 19 | 240 | 2.4 |
| Example 20 | 306 | 2.4 |
| Comparative Example 1 | 22 | 3.0 |
| Comparative Example 2 | 116 | 2.2 |
| Comparative Example 3 | 32 | 3.0 |
| Comparative Example 4 | 124 | 2.0 |
| Comparative Example 5 | 38 | 3.0 |
| Comparative Example 6 | 150 | 2.0 |
| Comparative Example 7 | 21 | 4.0 |
| Comparative Example 8 | 75 | 2.4 |
| Comparative Example 9 | 72 | 3.0 |
| Comparative Example 10 | 140 | 2.4 |

Per Table 1, the lower the energy, the higher the photosensitivity. In addition, the narrower the width, the higher the resolution.

Referring to Table 1, it can be noted that the photoresist composition according to Comparative Example 1 has a higher photosensitivity than those of the photoresist compositions according to Examples 1 to 4, but has a lower resolution than those of the photoresist compositions according to Examples 1 to 4. In addition, it can be noted that the photoresist composition according to Comparative Example 2 has a higher resolution than those of the photoresist compositions according to Examples 1 to 4, but has a lower photosensitivity than those of the photoresist compositions according to Examples 1 to 4. Furthermore, it can be noted that the photoresist composition according to Comparative Example 3 has a higher photosensitivity than those of the photoresist compositions according to Examples 5 to 8, but has a lower resolution than those of the photoresist compositions according to Examples 5 to 8. It can be noted that the photoresist composition according to Comparative Example 4 has a higher resolution than those of the photoresist compositions according to Examples 5 to 8, but has a lower photosensitivity than those of the photoresist compositions according to Examples 5 to 8. It can be noted that the photoresist composition according to Comparative Example 5 has a higher photosensitivity than those of the photoresist compositions according to Examples 9 to 12, but has a lower resolution than those of the photoresist compositions according to Examples 9 to 12. It can be noted that the photoresist composition according to Comparative Example 6 has a higher resolution than those of the photoresist compositions according to Examples 9 to 12, but has a lower photosensitivity than those of the photoresist compositions according to Examples 9 to 12.

Referring to Table 1, it can also be noted that the photoresist composition according to Comparative Example 7 has a higher photosensitivity than those of the photoresist compositions according to Examples 13 to 16, but has a lower resolution than those of the photoresist compositions according to Examples 13 to 16. It can be noted that the photoresist composition according to Comparative Example 8 has a higher resolution than those of the photoresist compositions according to Examples 13 to 16, but has a lower photosensitivity than those of the photoresist compositions according to Examples 13 to 16. In addition, it can be noted that the photoresist composition according to Comparative Example 9 has a higher photosensitivity than those of the photoresist compositions according to Examples 17 to 20, but has a lower resolution than those of the photoresist compositions according to Examples 17 to 20. It can be noted that the photoresist composition according to Comparative Example 10 has a higher resolution than those of the photoresist compositions according to Examples 17 to 20, but has a lower photosensitivity than those of the photoresist compositions according to Examples 17 to 20.

According to the above, it can be noted that a photoresist composition only including the benzophenone photosensitizer without the ethylidyne tris phenol photosensitizer has a high photosensitivity and a low resolution. In addition, it can be noted that a photoresist composition only including the ethylidyne tris phenol photosensitizer without the benzophenone photosensitizer has a high resolution and a low photosensitivity. Thus, it can be noted that the photosensitivity and the resolution are improved by using both the benzophenone photosensitizer and the ethylidyne tris phenol photosensitizer having a weight ratio in a range from about 20:80 to about 80:20.

In Examples 1 to 20, it can be noted that the photoresist composition according to Example 13 has a lower resolution than those of the photoresist compositions according to Examples 1, 5 and 9. It can be noted that the photoresist composition according to Example 17 has a lower photosensitivity than those of the photoresist compositions according to Examples 1, 5 and 9. In addition, it can be noted that the photoresist composition according to Example 14 has a lower resolution than those of the photoresist compositions according to Examples 2, 6 and 10. It can be noted that the photoresist composition according to Example 18 has a lower photosensitivity than those of the photoresist compositions according to Examples 2, 6 and 10.

According to the above, it can be noted that the resolution is decreased when a weight ratio of the m-cresol and the p-cresol is about 70:30, and the photosensitivity is decreased when a weight ratio of the m-cresol and the p-cresol is about 30:70. Thus, it can be noted that a weight ratio of the m-cresol to the p-cresol is preferably in a range from about 40:60 to about 60:40.

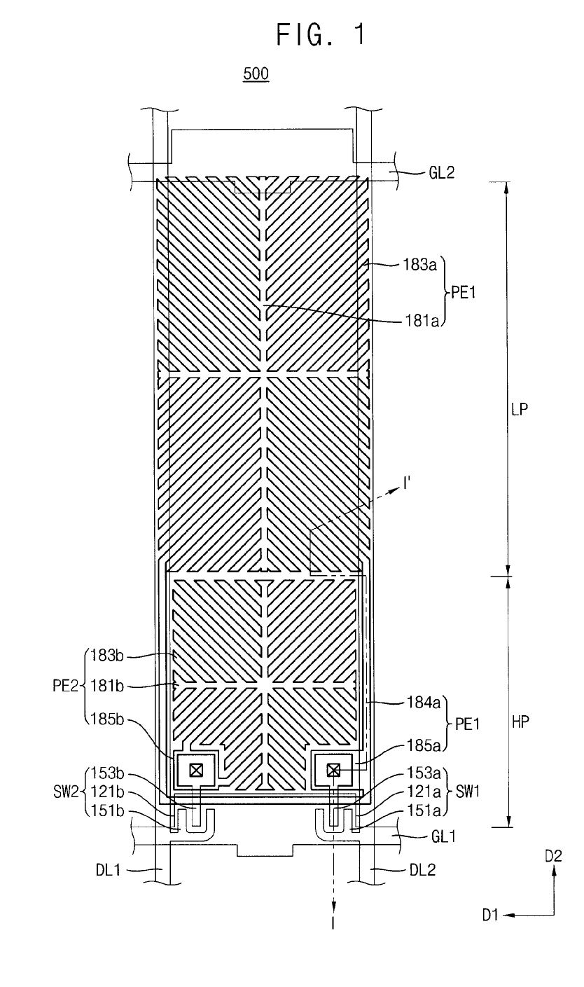

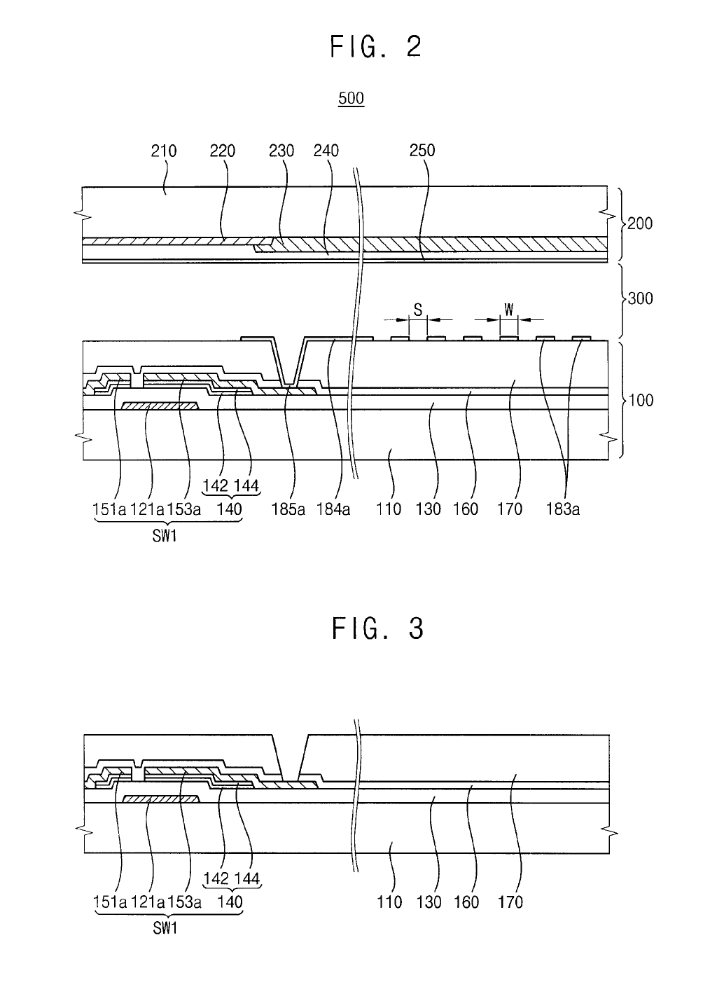

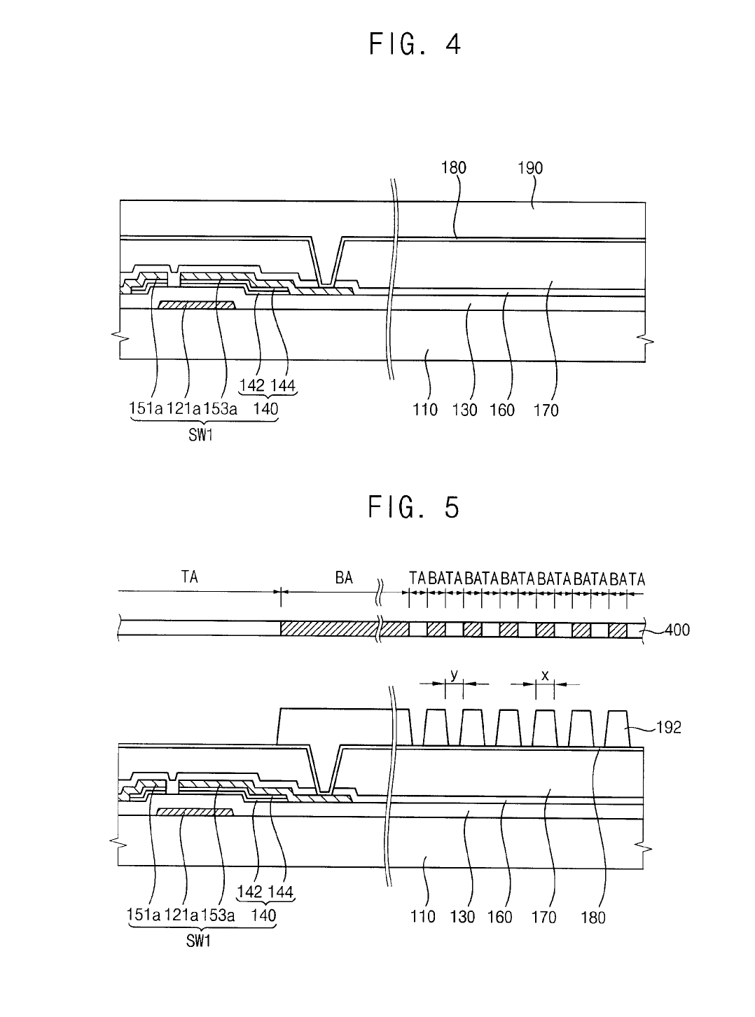

Hereinafter, a method of manufacturing a display substrate according to an exemplary embodiment of the invention is described with reference to the accompanying drawings. First, a display substrate will be described with reference to FIG. 1 and FIG. 2. Then, a method of manufacturing the display substrate shown in FIG. 1 and FIG. 2 will be described with reference to FIG. 3, FIG. 4 and FIG. 5.

FIG. 1 is a plan view illustrating a display panel according to an exemplary embodiment of the present invention. FIG. 2 is a cross-sectional view taken along line I-I′ in FIG. 1.

Referring to FIG. 1 and FIG. 2, a liquid crystal display (LCD) panel 500 includes a display substrate 100, an opposing substrate 200 facing the display substrate 100, and a liquid crystal layer 300 disposed between the display substrate 100 and the opposing substrate 200.

The display substrate 100 includes a first gate line GL1, a second gate line GL2, a first data line DL1, a second data line DL2, a first transistor SW1, a second transistor SW2, a first pixel electrode PE1, and a second pixel electrode PE2. These are formed on a first base substrate 110. The display substrate 100 may further include a gate insulation layer 130, a passivation layer 160 and an organic layer 170.

The first gate line GL1 and the second gate line GL2 extend in a first direction D1 of the LCD panel 500. The first gate line GL1 and the second gate line GL2 are arranged in parallel and spaced apart in a second direction D2. For example, the first direction D1 may be perpendicular to the second direction D2. The first gate line GL1 is electrically connected to the first transistor SW1 and the second transistor SW2. The first data line DL1 and the second data line DL2 extend in the second direction D2. The first data line DL1 and the second data line DL2 are arranged in parallel and spaced apart in the first direction D1. The first data line DL1 and the second data line DL2 cross each of the first gate line GL1 and the second gate line GL2.

The first transistor SW1 is connected to the first gate line GL1 and the second data line DL2. The first transistor SW1 includes a first gate electrode 121a connected to the first gate line GL1, a first source electrode 151 a connected to the second data line DL2, a first drain electrode 153a spaced apart from the first source electrode 151a, and a first active pattern 140. The second transistor SW2 is connected to the first gate line GL1 and the first data line DL1. The second transistor SW2 includes a second gate electrode 121b connected to the first gate line GL1, a second source electrode 151b connected to the first data line DL1, a second drain electrode 153b spaced apart from the second source electrode 151b, and a second active pattern (not shown).

The first pixel electrode PE1 is electrically connected to the first transistor SW1. The first pixel electrode PE1 receives a first voltage from the second data line DL2. The second pixel electrode PE2 is electrically connected to the second transistor SW2. The second pixel electrode PE2 receives a second voltage from the first data line DL1. The second voltage may be higher than the first voltage. A region including the first pixel electrode PE1 may define a low pixel LP of the LCD panel 500. A region including the second pixel electrode PE2 may define a high pixel HP of the LCD panel 500.

The first pixel electrode PE1 includes a plurality of first microelectrodes 183a, a first contact electrode 185a contacting with the first drain electrode 153a, and a bridge pattern 184a physically and electrically connecting the first contact electrode 185a to the microelectrodes 183a. The bridge pattern 184a surrounds the second pixel electrode PE2. The first microelectrodes 183a have a radial shape diverged from a first body portion 181a having a cross shape. The second pixel electrode PE2 includes a plurality of second microelectrodes 183b and a second contact electrode 185b contacting with the second drain electrode 153b. The second microelectrodes 183b have a radial shape diverged from a second body portion 181b having a cross shape.

The first microelectrodes 183a and the second microelectrodes 183b may be slanted to have an angle of about 45° or about 135° with respect to the first gate line GL1. A width “W” of the first microelectrodes 183a and the second microelectrodes 183b may be in a range from about 2.0 μm to about 2.8 μm. A slit is defined by the first microelectrodes 183a adjacent to each other. A slit width “S” may be in a range from about 2.0 μm to about 2.8 μm. The second microelectrodes 183b adjacent to each other may also define the slit.

The gate insulation layer 130 is formed on the first base substrate 110 including the first gate line GL1 and the second gate line GL2, the first gate electrode 121a and the second gate electrode 121b. The passivation layer 160 is formed on the first base substrate 110 including the first data line DL1 and the second data line DL2, the first source electrode 151a and the second source electrode 151b, the first drain electrode 153a and the second drain electrode 153b. The organic layer 170 is formed between the passivation layer 160 and the first pixel electrode PE1 and the second pixel electrode PE2 to planarize the display substrate 100. The passivation layer 160 and the organic layer 170 include a first contact hole exposing an edge portion of the first drain electrode 153a and a second contact hole exposing an edge portion of the second drain electrode 153b.

The opposing substrate 200 includes a light-blocking pattern 220 formed on a second base substrate 210 facing the display substrate 100, a color filter 230, an overcoating layer 240 and a common electrode layer 250. The common electrode layer 250 faces the first pixel electrode PE1 and the second pixel electrode PE2 and is formed on the entire surface of the second base substrate 210. The common electrode layer 250 generates an electric field direction of the liquid crystal layer 300 with the first pixel electrode PE1 and the second pixel electrode PE2 of the display substrate 100, although the common electrode layer 250 is not patterned by a photolithography process, thereby operating the LCD panel in a patterned vertical alignment (PVA) mode.

Method of Manufacturing a Display Substrate

FIG. 3, FIG. 4 and FIG. 5 are cross-sectional views illustrating a method of manufacturing the display substrate shown in FIG. 2.

Referring to FIG. 1 and FIG. 3, a gate metal layer is formed on the first base substrate 110 and patterned through a photolithography process to form a gate pattern. The gate pattern includes the first gate line GL1 and the second gate line GL2, and the first gate electrode 121a and the second gate electrode 121b.

The gate insulation layer 130 is formed on the first base substrate 110 including the gate pattern. The first active pattern 140 and the second active pattern (not shown) are formed on the gate insulation layer 130. The first active pattern 140 may include a semiconductor layer 142 and an ohmic contact layer 144 formed on the semiconductor layer 142.

A source metal layer is formed on the first base substrate 110 including the first active pattern 140 and the second active pattern and patterned through a photolithography process to form a source pattern. The source pattern includes the first data line DL1 and the second data line DL2, the first source electrode 151a and the second source electrode 151b, the first drain electrode 153a and the second drain electrode 153b.

The passivation layer 160 and the organic layer 170 are formed on the first base substrate 110 including the source pattern. The passivation layer 160 and the organic layer 170 are patterned through a photolithography process to form contact holes exposing each of an edge portion of the first drain electrode 153a and an edge portion of the second drain electrode 153b.

Referring to FIG. 4, a transparent electrode layer 180 is formed on the first base substrate 110 including the passivation layer 160 and the organic layer 170 having the contact holes. The transparent electrode layer 180 may be formed using indium tin oxide (ITO), indium zinc oxide (IZO), etc.

A photoresist layer 190 is formed on the first base substrate 110 including the transparent electrode layer 180. The photoresist layer 190 may be formed through spin-coating and/or slit-coating a photoresist composition on the first base substrate 110.

The photoresist composition includes a) a novolac resin, b) a benzophenone photosensitizer and an ethylidyne tris phenol photosensitizer in a weight ratio of the benzophenone photosensitizer to the ethylidyne tris phenol photosensitizer in a range from about 20:80 to about 80:20 based on a total weight of the benzophenone photosensitizer and the ethylidyne tris phenol photosensitizer, and c) an organic solvent. The benzophenone photosensitizer may be prepared by reacting a benzophenone compound with a quinone diazide compound. The ethylidyne tris phenol photosensitizer may be prepared by reacting an ethylidyne tris phenol compound with a quinone diazide compound. The novolac resin may be formed using a phenol compound including an m-cresol and a p-cresol in a weight ratio of the m-cresol to the p-cresol in a range from about 40:60 to about 60:40. The photoresist composition is substantially the same as the above-described photoresist composition according to an exemplary embodiment of the invention. Thus, any further repetitive description will be omitted here.

Referring to FIG. 5, a mask 400 is disposed over the photoresist layer 190. Light is irradiated to the photoresist layer 190 over the mask 400 to form a plurality of photoresist patterns 192. The mask 400 includes a light-transmitting portion TA and a light-blocking portion BA. The photoresist layer 190 exposed by the light is removed using a developing solution to expose a portion of the transparent electrode layer 180. The photoresist layer 190 that is not exposed by the light is not removed by the developing solution to remain on the first base substrate 110, thereby forming the photoresist patterns 192.

The photoresist composition includes the benzophenone photosensitizer and the ethylidyne tris phenol photosensitizer in a weight ratio in the range from about 20:80 to about 80:20 based on a total weight of the benzophenone photosensitizer and the ethylidyne tris phenol photosensitizer, thereby improving the photosensitivity of the photoresist composition. Thus, an energy required to form the photoresist patterns 192 may be decreased. In addition, the resolution of the photoresist composition is improved to form the photoresist patterns 192 having a width “x” in a range from about 2.0 μm to about 2.8 μm, independent of the resolution of the exposure apparatus. Furthermore, a distance “y” between the photoresist patterns 192 adjacent to each other may be in a range from about 2.0 μm to about 2.8 μm.

The transparent electrode layer 180 is patterned by using the photoresist patterns 192 as an etching mask. Thus, the transparent electrode layer 180 is patterned to form the first pixel electrode PE1 including the first microelectrodes 183a having a fine size and the second pixel electrode PE2 including the second microelectrodes 183b also having a fine size.

By improving the photosensitivity and the resolution of the photoresist composition, the manufacturing reliability of the first microelectrodes 183a and the second microelectrodes 183b may be improved.

According to the above, the photoresist composition is used in forming the first pixel electrode PE1 and the second pixel electrode PE2. Also, the photoresist composition is used in patterning the gate metal layer and/or patterning the source metal layer.

According to exemplary embodiments of the present invention, a micropattern having a higher resolution than the resolution of an exposure apparatus may be formed. Furthermore, a photoresist composition according to an embodiment of the present invention has a relatively high photosensitivity to decrease an amount of exposure and/or exposure time, thereby improving manufacturing reliability and productivity.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A photoresist composition, comprising:
a novolac resin;
a benzophenone photosensitizer and an ethylidyne tris phenol photosensitizer in a weight ratio of the benzophenone photosensitizer to the ethylidyne tris phenol photosensitizer in a range from about 20:80 to about 80:20 based on a total weight of the benzophenone photosensitizer and the ethylidyne tris phenol photosensitizer; and
an organic solvent.

2. The photoresist composition of claim 1, wherein the benzophenone photosensitizer comprises a resultant of a benzophenone compound and a quinone diazide compound reaction.

3. The photoresist composition of claim 1, wherein the benzophenone photosensitizer comprises a resultant of 2,3,4,4′-tetrahydroxybenzophenone and a quinone diazide compound reaction.

4. The photoresist composition of claim 1, wherein the ethylidyne tris phenol photosensitizer comprises a resultant of an ethylidyne tris phenol compound and a quinone diazide compound reaction.

5. The photoresist composition of claim 1, wherein the ethylidyne tris phenol photosensitizer comprises a resultant of 4,4′,4″-ethylidyne tris phenol and a quinone diazide compound reaction.

6. The photoresist composition of claim 1, wherein the weight ratio of the benzophenone photosensitizer to the ethylidyne tris phenol photosensitizer is about 40:60.

7. The photoresist composition of claim 1, wherein the novolac resin comprises a phenol compound including an m-cresol and a p-cresol in a weight ratio of the m-cresol to the p-cresol in a range from about 40:60 to about 60:40.

8. The photoresist composition of claim 1, wherein the novolac resin comprises a phenol compound including an m-cresol and a p-cresol in a weight ratio of the m-cresol to the p-cresol of about 50:50.

9. The photoresist composition of claim 1, wherein the novolac resin has a weight average molecular weight in a range from about 3,000 to about 15,000.

10. The photoresist composition of claim 1, wherein a content of the novolac resin is in a range from about 5 percent by weight to about 20 percent by weight, a content of the photosensitizers is in a range from about 2 percent by weight to about 10 percent by weight, and a content of the organic solvent is in a range from about 75 percent by weight to about 90 percent by weight of the composition.

11. A method of manufacturing a display substrate, the method comprising:
forming a switching element connected to a gate line and a data line;
forming a transparent electrode layer on a substrate having the switching element;
forming a photoresist pattern using a photoresist composition comprising: a) a novolac resin, b) a benzophenone photosensitizer and an ethylidyne tris phenol photosensitizer in a weight ratio of the benzophenone photosensitizer to the ethylidyne tris phenol photosensitizer in a range from about 20:80 to about 80:20 based on a total weight of the benzophenone photosensitizer and the ethylidyne tris phenol photosensitizer, and c) an organic solvent, the photoresist pattern formed on the transparent electrode layer; and
patterning the transparent electrode layer using the photoresist pattern as an etching mask to form a pixel electrode comprising a plurality of microelectrodes.

12. The method of claim 11, wherein each of the microelectrodes has a width in a range from about 2.0 μm to about 2.8 μm.

13. The method of claim 11, wherein a distance between the microelectrodes adjacent to each other is in a range from about 2.0 μm to about 2.8 μm.

14. The method of claim 11, further comprising preparing the benzophenone photosensitizer by reacting a benzophenone compound with a quinone diazide compound.

15. The method of claim 11, further comprising preparing the ethylidyne tris phenol photosensitizer by reacting an ethylidyne tris phenol compound with a quinone diazide compound.

16. The method of claim 11, further comprising forming the novolac resin using a phenol compound including an m-cresol and a p-cresol in a weight ratio of the m-cresol to the p-cresol in a range from about 40:60 to about 60:40.

17. The method of claim 11, wherein the novolac resin has a weight average molecular weight in a range from about 3,000 to about 15,000.

18. The method of claim 11, wherein a content of the novolac resin is in a range from about 5 percent by weight to about 20 percent by weight, a content of the photosensitizer is in a range from about 2 percent by weight to about 10 percent by weight, and a content of the organic solvent is in a range from about 75 percent by weight to about 90 percent by weight.
